(19) United States
(12) Patent Application Publication
(10) Pub. No.: US 2025/0266366 A1
(43) Pub. Date: Aug. 21, 2025

(54) PACKAGING STRUCTURE, METHOD FOR PREPARING PACKAGING STRUCTURE, AND ELECTRONIC DEVICE

(71) Applicant: VIVO MOBILE COMMUNICATION CO., LTD., Dongguan (CN)

(72) Inventor: Dou JIN, Dongguan (CN)

(73) Assignee: VIVO MOBILE COMMUNICATION CO., LTD., Dongguan (CN)

(21) Appl. No.: 19/186,838

(22) Filed: Apr. 23, 2025

Related U.S. Application Data
(63) Continuation of application No. PCT/CN2023/125922, filed on Oct. 23, 2023.

(30) Foreign Application Priority Data
Oct. 27, 2022 (CN) 202211323801.2

(51) Int. Cl. H01L 23/538; H01L 23/00; H01L 23/31; H01L 25/00; H01L 25/03

(52) U.S. Cl. CPC H01L 23/5389; H01L 23/3107; H01L 23/5385; H01L 25/03; H01L 25/50; H01L 24/16; H01L 2224/16227

(57) ABSTRACT

A packaging structure, a method for preparing the packaging structure, and an electronic device are provided. The packaging structure includes a substrate, a first chip, a first conductive member, and a first filling adhesive layer. A groove is provided on the substrate, a first wiring layer is arranged on a bottom wall of the groove, the first chip is arranged in the groove, a first surface of the first chip is electrically connected to the first wiring layer, one end of the first conductive member is electrically connected to the first wiring layer, the first filling adhesive layer is filled in the groove, and the first filling adhesive layer is flush with a surface on which a notch of the groove is located. Both the other end of the first conductive member and a second surface of the first chip are exposed from the first filling adhesive layer.

### CROSS-REFERENCE TO RELATED APPLICATIONS

This application is a continuation of International Application No. PCT/CN2023/125922, filed Oct. 23, 2023, which claims priority to Chinese Patent Application No. 202211323801.2, filed Oct. 27, 2022. The entire contents of each of the above-referenced applications are expressly incorporated herein by reference.

### TECHNICAL FIELD

The present application relates to the field of semiconductor packaging technologies, and in particular, to a packaging structure, a method for preparing the packaging structure, and an electronic device.

### BACKGROUND

With the development of electronic technologies, semiconductor packaging tends to develop in a direction of high density, low power consumption, and miniaturization. A fan-out packaging technology breaks away from a limitation of a conventional chip on a range and can integrate a plurality of chips in a package.

In the related art, a chip is mounted in a groove of a substrate in a packaging structure with a chip surface facing upward. That is, an electrical connection surface of the chip faces a direction of a notch of the groove of the substrate, to implement electrical connection between the chip and another circuit structure. To eliminate a step difference between the chip in the groove and the substrate at the notch of the groove, a thick insulating dielectric layer needs to be laid on a surface of the notch of the groove to eliminate the difference. The thick insulating dielectric layer laid on the surface of the notch of the groove may result in a problem of a large overall thickness of the packaging structure.

### SUMMARY

The present application discloses a packaging structure, a method for preparing the packaging structure, and an electronic device.

According to a first aspect, this application discloses a packaging structure, including a substrate, a first chip, a first conductive member, and a first filling adhesive layer. A groove is provided on the substrate, a first wiring layer is arranged on a bottom wall of the groove, the first chip is arranged in the groove, a first surface of the first chip is electrically connected to the first wiring layer, one end of the first conductive member is electrically connected to the first wiring layer, the first filling adhesive layer is filled in the groove, and the first filling adhesive layer is flush with a surface on which a notch of the groove is located. Both the other end of the first conductive member and a second surface of the first chip are exposed from the first filling adhesive layer, and are flush with the surface on which the notch of the groove is located, the first surface of the first chip is opposite to the second surface of the first chip, and the first surface of the first chip is an electrical connection surface of the first chip.

According to a second aspect, this application discloses an electronic device, including the packaging structure according to the first aspect.

According to a third aspect, this application discloses a method for preparing a packaging structure, including:
providing a groove on a substrate;
preparing a first wiring layer on a bottom wall of the groove;
arranging a first chip in the groove, and electrically connecting a first surface of the first chip to the first wiring layer;
preparing a first conductive member, where one end of the first conductive member is electrically connected to the first wiring layer;
filling an adhesive in the groove to form a first filling adhesive layer, where the first filling adhesive layer at least covers a surface on which a notch of the groove is located;
performing grinding processing on a side of the first filling adhesive layer facing away from the substrate, to enable the first filling adhesive layer to be flush with a surface on which the notch of the groove is located, and enable the other end of the first conductive member and a second surface of the first chip to be exposed from the first filling adhesive layer, where the first surface of the first chip is opposite to the second surface of the first chip.

The technical solution adopted in the present application can achieve the following technical effects.

In the packaging structure disclosed in the embodiments of this application, the first wiring layer is arranged on the bottom wall of the groove provided on the substrate, so that the first surface of the first chip can be electrically connected to the first wiring layer. One end of the first conductive member is electrically connected to the first wiring layer, and then after the first filling adhesive layer is filled in the groove, the other end of the first conductive member and the second surface of the first chip are exposed from the first filling adhesive layer. Because the second surface of the first chip is not the electrical connection surface, grinding processing can be performed on a side of the first filling adhesive layer facing away from the first chip, to enable the second surface of the first chip, the other end of the first conductive member, and the first filling adhesive layer to be flush with each other, so as to avoid formation of a step difference between the first chip and the notch of the groove. The packaging structure can be thinned by grinding processing, thereby resolving the problem that the packaging structure is thick in related art.

### BRIEF DESCRIPTION OF THE DRAWINGS

FIG. 1 is a schematic diagram of a packaging structure disclosed in an embodiment of the present application;

FIG. 2 is a partial schematic diagram of FIG. 1;

FIG. 3 is a schematic diagram of a structure in which a groove is provided on a substrate;

FIG. 4 is a schematic diagram of preparing a first wiring layer and a first conductive member on a bottom wall of a groove;

FIG. 5 is a schematic diagram showing electrical connection between a first chip and a first wiring layer;

FIG. 6 is a schematic diagram in which a first filling adhesive layer is filled;

FIG. 7 is a schematic diagram in which grinding is performed on a first filling adhesive layer;

FIG. 8 is a schematic diagram in which a first dielectric layer and a second wiring layer are arranged;

FIG. 9 is a schematic diagram showing electrical connection between a second chip and a second wiring layer;

FIG. 10 is a schematic diagram in which a second conductive member is arranged;

FIG. 11 is a schematic diagram in which a second filling adhesive layer is arranged;

FIG. 12 is a schematic diagram in which grinding is performed on a second filling adhesive layer;

FIG. 13 is a flowchart of a method for preparing a packaging structure.

### REFERENCE NUMERALS

110—Substrate, 111—groove,
120—first chip, 130—first conductive member, 140—first filling adhesive layer,
150—first wiring layer,
210—first dielectric layer, 220—second wiring layer,
310—second chip, 320—second filling adhesive layer, 330—second conductive member,
410—second dielectric layer, 420—third wiring layer, and
510—third conductive member.

### DETAILED DESCRIPTION

To clearly state the objectives, technical solutions, and advantages of the present application, the technical solutions of the present application will be described below with reference to exemplary embodiments of the present application and the accompanying drawings. It is clear that described embodiments are merely some but not all of embodiments of the present application. All other embodiments obtained by a person of ordinary skill in the art based on embodiments of the present application without creative efforts shall fall within the protection scope of the present application.

The following describes the technical solution disclosed in each embodiment of the present application in detail with reference to the accompanying drawings.

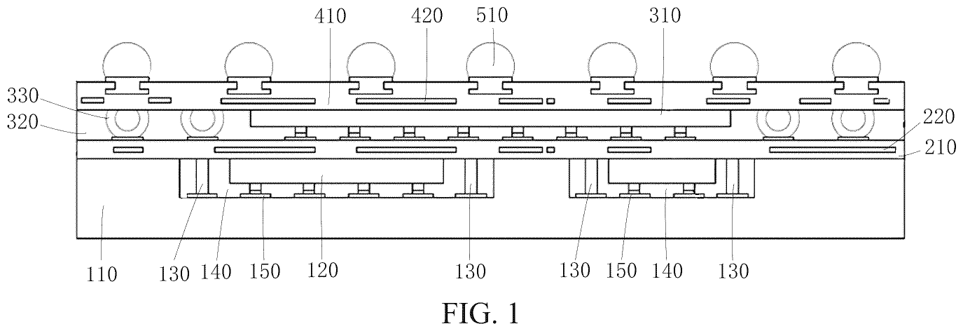

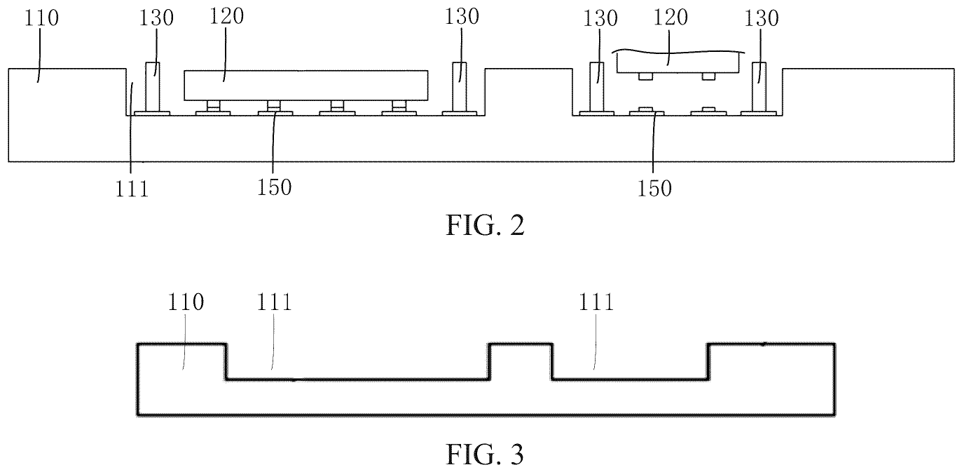

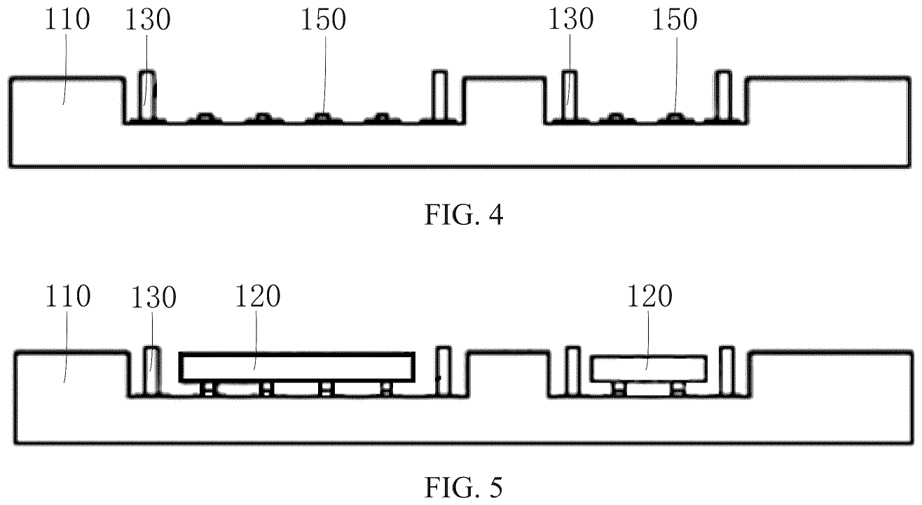

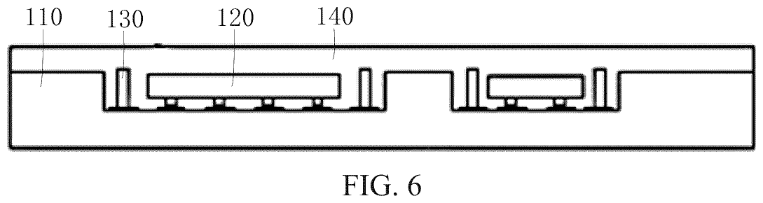

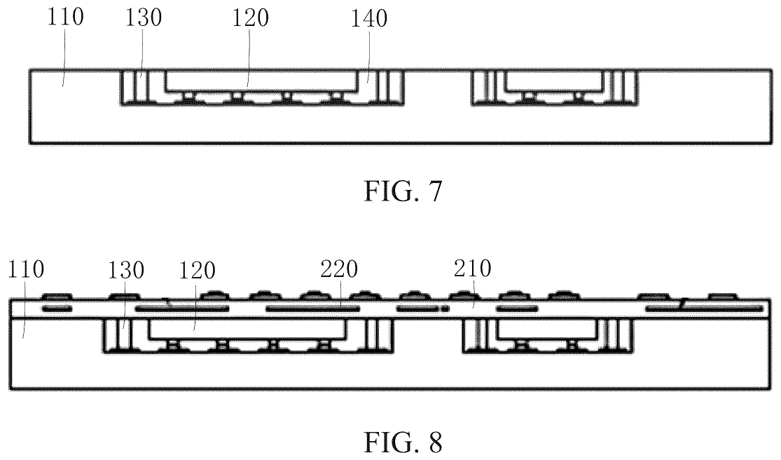

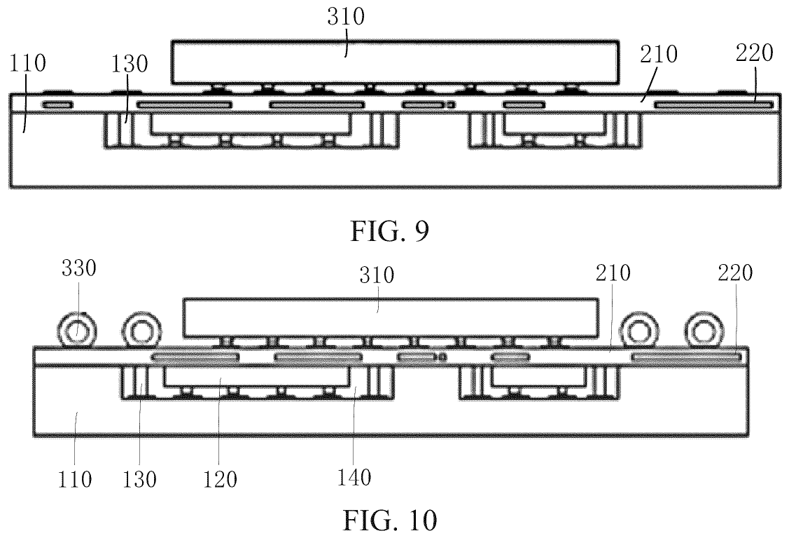

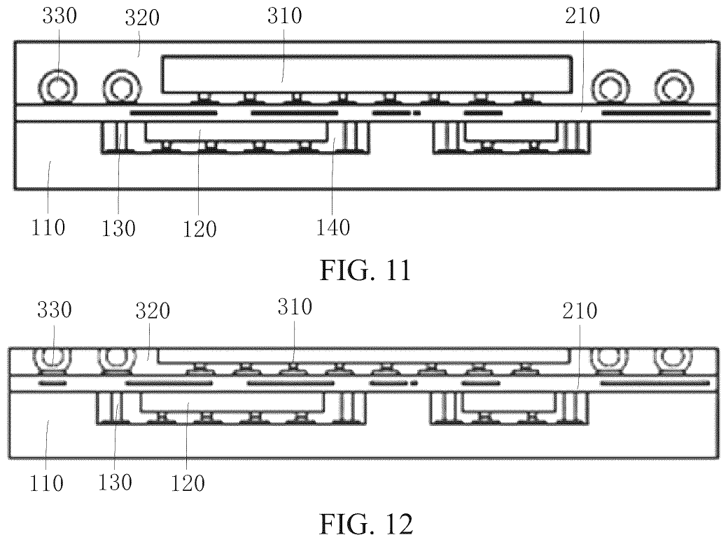

Refer to FIG. 1 to FIG. 12. Embodiments of the present application discloses a packaging structure. The disclosed packaging structure includes a substrate 110, a first chip 120, a first conductive member 130, and a first filling adhesive layer 140.

A groove 111 is provided on the substrate 110, and a first wiring layer 150 is arranged on a bottom wall of the groove 111. The first wiring layer 150 may be a single layer or a plurality of layers. A quantity of layers of the first wiring layer 150 is not specifically limited herein, and wiring can be performed according to actual conditions. The first chip 120 is arranged in the groove 111. A first surface of the first chip 120 is electrically connected to the first wiring layer 150. The first surface of the first chip 120 is an electrical connection surface of the first chip 120. Micro bumps may be arranged on both the first surface of the first chip 120 and the first wiring layer 150. The micro bump on the first surface of the first chip 120 is configured to bond with the micro bump on the first wiring layer 150, to implement electrical connection between the first chip 120 and the first wiring layer 150.

One end of the first conductive member 130 is electrically connected to the first wiring layer 150, the first filling adhesive layer 140 is filled in the groove 111, and the first filling adhesive layer 140 is flush with a surface on which a notch of the groove 111 is located, to enable the first filling adhesive layer 140 to wrap the first conductive member 130 and a part of the first chip 120 located in the groove 111 to package the first chip 120. The first conductive member 130 may be a copper column. In some embodiments, the first conductive member may also be another conductive member.

Both the other end of the first conductive member 130 and a second surface of the first chip 120 are exposed from the first filling adhesive layer 140, and are flush with the surface on which the notch of the groove 111 is located. The other end of the first conductive member 130 is used to be electrically connected to another external circuit or component, to enable the first chip 120 to be electrically connected to the another external circuit or component through the first surface of the first chip 120, the first wiring layer 150, and the first conductive member 130 in sequence.

The first surface of the first chip 120 is opposite to the second surface of the first chip 120, and the first surface of the first chip 120 is the electrical connection surface of the first chip 120. The second surface of the first chip 120 can be used to package a circuit structure in the first chip 120, but does not constitute the circuit structure of the first chip 120. The second surface of the first chip 120 may be at a distance from the circuit structure of the first chip 120, so that grinding processing can be performed on the second surface of the first chip 120.

In a specific process, the groove 111 is etched on the substrate 110, a size of the groove 111 is greater than a size of the first chip 120, the first wiring layer 150 is prepared on the bottom wall of the first groove 111, and the first conductive member 130 is prepared. Then, the first surface of the first chip 120 is electrically connected to the first wiring layer 150, and the first conductive member 130 is located between the first chip 120 and a side wall of the groove 111. After the first chip 120 is electrically connected to the first wiring layer 150, an adhesive is filled into the groove 111 to form the first filling adhesive layer 140. In a preparation process, after the first chip 120 is electrically connected to the first wiring layer 150, the second surface of the first chip 120 may be higher than the surface on which the notch of the groove 111 is located, or lower than the surface on which the notch of the groove 111 is located. The first filling adhesive layer 140 at least covers the notch of the groove 111, and the first filling adhesive layer 140 may also form an adhesive layer that is higher than the surface on which the notch of the groove 111 is located. After the first filling adhesive layer 140 is formed, grinding processing is performed on a side of the first filling adhesive layer 140 facing away from the substrate 110, and the other end of the first conductive member 130 is exposed from the first filling adhesive layer 140 for electrical connection with the another circuit structure. In addition, performing grinding processing on a layer of the first filling adhesive layer 140 facing away from the substrate 110 can reduce an overall thickness of the packaging structure, and the first chip 120 is flush with the surface on which the notch of the groove 111 is located without any step difference.

In the packaging structure disclosed in the embodiments of this application, the first wiring layer 150 is arranged on the bottom wall of the groove 111 provided on the substrate 110, so that the first surface of the first chip 120 can be electrically connected to the first wiring layer 150. One end of the first conductive member 130 is electrically connected to the first wiring layer 150, and then after the first filling adhesive layer 140 is filled in the groove 111, the other end of the first conductive member 130 and the second surface of the first chip 120 are exposed from the first filling adhesive layer 140. Because the second surface of the first chip 120 is not the electrical connection surface, grinding processing can be performed on a side of the first filling adhesive layer 140 facing away from the first chip 120, to enable the second surface of the first chip 120, the other end of the first conductive member 130, and the first filling adhesive layer 140 to be flush with each other, so as to avoid formation of a step difference between the first chip 120 and the notch of the groove 111. The packaging structure can be thinned by grinding processing, thereby resolving a problem that the packaging structure is thick in related art. In addition, grinding may be performed on the second surface of the first chip 120 to make the first chip 120 thinner. The thinner first chip 120 is further beneficial to heat dissipation of the first chip 120.

In an embodiment, the packaging structure may further include a first dielectric layer 210 and a second wiring layer 220, the first dielectric layer 210 may be arranged on the substrate 110 and covers the notch of the groove 111, the second wiring layer 220 may be arranged in the first dielectric layer 210, and the other end of the first conductive member 130 may be electrically connected to the second wiring layer 220.

The first dielectric layer 210 is arranged on the substrate 110, and the first dielectric layer 210 covers the notch of the groove 111, so that the first dielectric layer 210 can further protect the first chip 120, and the first chip 120 can be well-packaged in the groove 111. The second wiring layer 220 is arranged in the first dielectric layer 210, so that the second wiring layer 220 can be protected by the first dielectric layer 210, and after the other end of the first conductive member 130 is electrically connected to the second wiring layer 220, the other end of the first conductive member 130 may be more flexibly electrically connected to the another circuit structure through the second wiring layer 220.

In some embodiments, a quantity of grooves 111, a quantity of first chips 120, and a quantity of first conductive members 130 are more than one. The plurality of grooves 111 may be spaced apart, the plurality of first chips 120 may be arranged in the plurality of grooves 111 in a one-to-one correspondence, the plurality of first conductive members 130 surrounding the corresponding first chip 120 may be arranged in each of the grooves 111, and the other ends of the plurality of first conductive members 130 are electrically connected through the second wiring layer 220. In some embodiments, the plurality of first chips 120 may be different chips. In some embodiments, the plurality of first chips 120 may also be the same chip.

In the embodiments of this application, the plurality of grooves 111, the plurality of first chips 120, and the plurality of first conductive members 130 are arranged. The plurality of first chips 120 are arranged in the plurality of grooves 111 in a one-to-one correspondence, the plurality of first conductive members 130 surrounding the corresponding first chip 120 are arranged in each of the grooves 111, and the other ends of the plurality of first conductive members 130 are electrically connected through the second wiring layer 220, so that the plurality of first chips 120 can be electrically connected through the second wiring layer 220.

To further improve an integration capability of the packaging structure, in some embodiments, the packaging structure may further include a second chip 310. The second chip 310 may be arranged on a side of the first dielectric layer 210 facing away from the first chip 120, and the second chip 310 may be electrically connected to the second wiring layer 220. The second chip 310 may be electrically connected to the first chip 120 through the second wiring layer 220.

In the embodiments of this application, the second chip 310 is arranged on a side of the first dielectric layer 210 facing away from the first chip 120, so that the integration capability of the packaging structure is high. In addition, the second chip 310 is electrically connected to the second wiring layer 220, so that the electrical connection between the second chip 310 and the first chip 120 can be implemented, thereby implementing information exchange between a plurality of chips. The second chip 310 is arranged on a side facing away from the first chip 120, which can avoid a problem of an overall long length of the packaging structure caused by the first chip 120 and the second chip 310 being arranged on a same side.

Further, the first surface of the second chip 310 may be electrically connected to the second wiring layer 220. A second surface of the second chip 310 may be an electrical connection surface. The packaging structure may further include a second filling adhesive layer 320 and a second conductive member 330. The second filling adhesive layer 320 is connected to the first dielectric layer 210, and covers the second chip 310 and the second conductive member 330. A first end of the second conductive member 330 is electrically connected to the second wiring layer 220. The second surface of the second chip 310 and a second end of the second conductive member 330 are exposed from a surface of the second filling adhesive layer 320, the second surface of the second chip 310 is opposite to the first surface of the second chip 310, and the first surface of the second chip 310 is an electrical connection surface of the second chip 310. The second surface of the second chip 310 is at a distance from a circuit structure of the second chip 310. Grinding processing may be performed on the second surface of the second chip 310, so that the second surface is thinner, or other processes may be performed on the second surface of the second chip 310.

In a specific process, after the first surface of the second chip 310 is electrically connected to the second wiring layer 220 and the first end of the second conductive member 330 is electrically connected to the second wiring layer 220, the second filling adhesive layer 320 is arranged to cover the second chip 310 and the second conductive member 330. The second filling adhesive layer 320 may cover the second surface of the second chip 310 and the second end of the second conductive member 330 and then perform grinding processing, to enable the second surface of the second chip 310 and the second end of the second conductive member 330 to be exposed from the surface of the second filling adhesive layer 320. In some embodiments, when the second filling adhesive layer 320 is filled, the second surface of the second chip 310 and the second end of the second conductive member 330 are directly exposed from the surface of the second filling adhesive layer 320. After the second filling adhesive layer 320 is arranged, grinding processing can be performed on a side of the second filling adhesive layer 320 facing away from the first filling adhesive layer 140, to enable the second surface of the second chip 310 and the second end of the second conductive member 330 to be exposed from the surface of the second filling adhesive layer 320. This can ensure that both the second surface of the second chip 310 and the second end of the second conductive member 330 are flush with the second filling adhesive layer 320. In addition, a thickness of the second filling adhesive layer 320 may be further reduced by grinding, thereby reducing an overall thickness of the packaging structure.

The first surface of the second chip 310 is electrically connected to the second wiring layer 220, and the second filling adhesive layer 320 is connected to the first dielectric layer 210 and covers the second chip 310 and the second conductive member 330, the first end of the second conductive member 330 is electrically connected to the second wiring layer 220, the second surface of the second chip 310 and the second end of the second conductive member 330 are exposed from the surface of the second filling adhesive layer 320, so that the second filling adhesive layer 320 can protect the second chip 310, and the second end of the second conductive member 330 is exposed from the second filling adhesive layer 320, to implement electrical connection between the second wiring layer 220 and the external circuit.

In some embodiments, the second conductive member 330 may be a copper core ball. For example, the copper core ball may include a copper ball, a nickel-plated layer, and a tin-plated layer. The nickel-plated layer and the tin-plated layer may be coated on the copper ball to form a composite copper core ball.

In some embodiments, the packaging structure may further include a second dielectric layer 410 and a third wiring layer 420, the second dielectric layer 410 may be arranged on the second filling adhesive layer 320 and covers the second surface of the second chip 310 and the second end of the second conductive member 330, the third wiring layer 420 may be arranged in the second dielectric layer 410, and the second end of the second conductive member 330 is electrically connected to the third wiring layer 420.

The second dielectric layer 410 and the third wiring layer 420 are arranged, so that the second dielectric layer 410 can cover the second surface of the second chip 310 and the second end of the second conductive member 330 to well package the second chip 310 and the second conductive member 330, and can further protect the second chip 310 and the second conductive member 330. The third wiring layer 420 is arranged in the second dielectric layer 410, so that the second dielectric layer 410 can protect the third wiring layer 420. The second end of the second conductive member 330 is electrically connected to the third wiring layer 420, so that the second end of the second conductive member 330 is more flexibly connected to the external circuit structure.

To facilitate electrical connection between the packaging structure and the external circuit structure, in some embodiments, the packaging structure may further include a third conductive member 510. The third conductive member 510 may be arranged on a side of the second dielectric layer 410 facing away from the first conductive member 130. A first end of the third conductive member 510 may be electrically connected to the third wiring layer 420. In some embodiments, the third conductive member 510 may be a solder ball, a wire, or the like.

The third conductive member 510 is arranged on a side of the second dielectric layer 410 facing away from the first conductive member 130, so that the first end of the third conductive member 510 is electrically connected to the third wiring layer 420. This helps the packaging structure to be electrically connected to the external circuit structure through the third conductive member 510.

In some embodiments, the substrate 110 may be a silicon wafer. The substrate 110 is set as the silicon wafer, which not only can improve strength of the packaging structure, but also can resolve a problem of thermal expansion mismatch between a resin molding compound and a chip in the related art by using the resin molding compound as the substrate 110.

This application further discloses an electronic device. The disclosed electronic device includes the packaging structure in the foregoing embodiments. When the electronic device uses the foregoing packaging structure, it may be beneficial to a design of the electronic device to be lighter and thinner.

The electronic device may be a mobile phone, a tablet, a game console, or the like. The electronic device is not specifically limited herein.

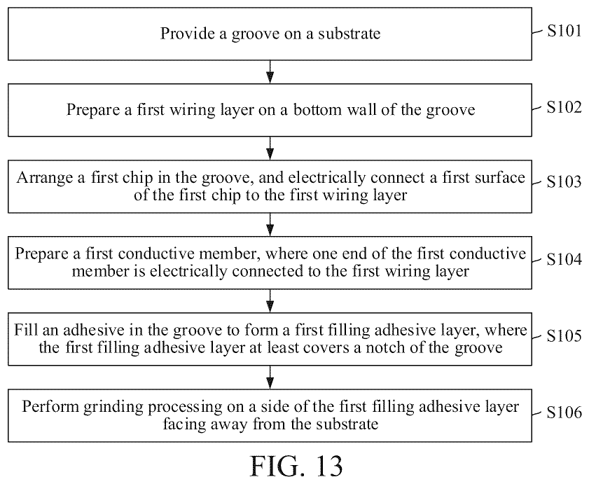

Refer to FIG. 13. This application further discloses a method for preparing a packaging structure. The disclosed preparation method includes:

S101: Provide a groove 111 on a substrate 110.

S102: Prepare a first wiring layer 150 on a bottom wall of the groove 111.

S103: Arrange a first chip 120 in the groove 111, and electrically connect a first surface of the first chip 120 to the first wiring layer 150.

S104: Prepare a first conductive member 130, where one end of the first conductive member 130 is electrically connected to the first wiring layer 150.

S105: Fill an adhesive in the groove 111 to form a first filling adhesive layer 140, where the first filling adhesive layer 140 at least covers a notch of the groove 111.

S106: Perform grinding processing on a side of the first filling adhesive layer 140 facing away from the substrate 110, to enable the first filling adhesive layer 140 to be flush with a surface on which the notch of the groove 111 is located, and enable the other end of the first conductive member 130 and a second surface of the first chip 120 to be exposed from the first filling adhesive layer 140.

The first surface of the first chip 120 is opposite to the second surface of the first chip 120.

Components of the packaging structure in the method for preparing the packaging structure disclosed in this application are the same as or similar to components in the foregoing embodiments, and the components can be referenced to each other. This is not described in detail herein.

In this application, after the first filling adhesive layer 140 is filled, grinding processing can be performed on a side of the first filling adhesive layer 140 facing away from the substrate 110, to enable the first chip 120 to be flush with the surface on which the notch of the groove 111 is located, thereby avoiding formation of a step difference between the first chip 120 and the plane on which the notch of the groove 111 is located. The grinding processing can further make the packaging structure thinner, and the thinner first chip 120 is beneficial to heat dissipation of the first chip 120.

In some embodiments, after the performing grinding processing on a side of the first filling adhesive layer 140 facing away from the substrate 110, the disclosed method for preparing a packaging structure further includes the following steps.

Step A1: Prepare a first dielectric layer 210 and a second wiring layer 220 on a substrate 110, where the first dielectric layer 210 covers a notch of a groove 111, the second wiring layer 220 is located in the first dielectric layer 210, and the other end of a first conductive member 130 is electrically connected to the second wiring layer 220.

Step A2: Arrange a second chip 310 on a side of the first dielectric layer 210 facing away from a first chip 120, and electrically connect a first surface of the second chip 310 to the second wiring layer 220.

Step A3: Prepare a second conductive member 330, where one end of the second conductive member 330 is electrically connected to the second wiring layer 220.

Step A4: Prepare a second filling adhesive layer 320 on the first dielectric layer 210, where the second filling adhesive layer 320 covers the second chip 310 and the second conductive member 330.

Step A5. Perform grinding processing on a side of the second filling adhesive layer 320 facing away from the substrate 110, to enable a second surface of the second chip 310, a second end of the second conductive member 330, and the second filling adhesive layer 320 to be flush with each other, and enable the second surface of the second chip 310 and the second end of the second conductive member 330 to be exposed from the second filling adhesive layer 320.

The first surface of the second chip 310 is opposite to the second surface of the second chip 310.

Components of the packaging structure disclosed in the embodiments of this application are the same as or similar to components in the foregoing embodiments, and the components can be referenced to each other. This is not described in detail herein.

The first dielectric layer 210 is arranged on the substrate 110, and the first dielectric layer 210 covers the notch of the groove 111, so that the first dielectric layer 210 can further protect the first chip 120, and the first chip 120 can be well-packaged in the groove 111. The second wiring layer 220 is arranged in the first dielectric layer 210, so that the second wiring layer 220 can be protected by the first dielectric layer 210, and after the other end of the first conductive member 130 is electrically connected to the second wiring layer 220, the other end of the first conductive member 130 may be more flexibly electrically connected to another circuit structure through the second wiring layer 220.

The second chip 310 is arranged on a side of the first dielectric layer 210 facing away from the first chip 120, so that an integration capability of the packaging structure is high. In addition, the second chip 310 is electrically connected to the second wiring layer 220, so that the electrical connection between the second chip 310 and the first chip 120 can be implemented, thereby implementing information exchange between a plurality of chips. The second chip 310 is arranged on a side facing away from the first chip 120, which can avoid a problem of an overall long length of the packaging structure caused by the first chip 120 and the second chip 310 being arranged on a same side. The first surface of the second chip 310 is electrically connected to the second wiring layer 220, and the second filling adhesive layer 320 is connected to the first dielectric layer 210 and covers the second chip 310 and the second conductive member 330, the first end of the second conductive member 330 is electrically connected to the second wiring layer 220, the second surface of the second chip 310 and the second end of the second conductive member 330 are exposed from the surface of the second filling adhesive layer 320, so that the second filling adhesive layer 320 can protect the second chip 310, and the second end of the second conductive member 330 is exposed from the second filling adhesive layer 320, to implement electrical connection between the second wiring layer 220 and the external circuit.

In some embodiments, after the performing grinding processing on a side of the second filling adhesive layer 320 facing away from the substrate 110, to enable a second surface of the second chip 310, a second end of the second conductive member 330, and the second filling adhesive layer 320 to be flush with each other, and enable the second surface of the second chip 310 and the second end of the second conductive member 330 to be exposed from the second filling adhesive layer 320, the disclosed preparation method further includes the following step.

Step B1: Prepare a second dielectric layer 410 and a third wiring layer 420 on the second filling adhesive layer 320. The second dielectric layer 410 covers the second surface of the second chip 310 and the second end of the second conductive member 330, the third wiring layer 420 is arranged in the second dielectric layer 410, and the second end of the second conductive member 330 is electrically connected to the third wiring layer 420.

The second dielectric layer 410 and the third wiring layer 420 are arranged, so that the second dielectric layer 410 can cover the second surface of the second chip 310 and the second end of the second conductive member 330 to well package the second chip 310 and the second conductive member 330, and can further protect the second chip 310 and the second conductive member 330. The third wiring layer 420 is arranged in the second dielectric layer 410, so that the second dielectric layer 410 can protect the third wiring layer 420. The second end of the second conductive member 330 is electrically connected to the third wiring layer 420, so that the second end of the second conductive member 330 is more flexibly connected to the external circuit structure.

The foregoing embodiments of the present application focus on differences between various embodiments. As long as different optimization features between various embodiments are not contradictory, the embodiments can be combined to form a better embodiment. Considering simplicity of the specification, this is not described in detail herein.

The embodiments of the present application are described above with reference to the accompanying drawings, but the present application is not limited to the foregoing specific implementations, which are merely illustrative rather than limited. Under the inspiration of the present application, a person of ordinary skill in the art can make many forms without departing from the scope of the present application and the protection of the claims, all of which fall within the protection of the present application.

What is claimed is:

1. A packaging structure, comprising a substrate, a first chip, a first conductive member, and a first filling adhesive layer, wherein:
a groove is provided on the substrate, a first wiring layer is arranged on a bottom wall of the groove, the first chip is arranged in the groove, a first surface of the first chip is electrically connected to the first wiring layer, one end of the first conductive member is electrically connected to the first wiring layer, the first filling adhesive layer is filled in the groove, and the first filling adhesive layer is flush with a surface on which a notch of the groove is located; and
both the other end of the first conductive member and a second surface of the first chip are exposed from the first filling adhesive layer, and are flush with the surface on which the notch of the groove is located, the first surface of the first chip is opposite to the second surface of the first chip, and the first surface of the first chip is an electrical connection surface of the first chip.

2. The packaging structure according to claim 1, wherein the packaging structure further comprises a first dielectric layer and a second wiring layer, the first dielectric layer is arranged on the substrate and covers the notch of the groove, the second wiring layer is arranged in the first dielectric layer, and the other end of the first conductive member is electrically connected to the second wiring layer.

3. The packaging structure according to claim 2, wherein a quantity of grooves, a quantity of first chips, and a quantity of first conductive members are more than one, the grooves are spaced apart, the first chips are arranged in the grooves in a one-to-one correspondence, the first conductive members surrounding the corresponding first chip are arranged in each of the grooves, and the other ends of the first conductive members are electrically connected through the second wiring layer.

4. The packaging structure according to claim 2, wherein the packaging structure further comprises a second chip, the second chip is arranged on a side of the first dielectric layer facing away from the first chip, and the second chip is electrically connected to the second wiring layer.

5. The packaging structure according to claim 4, wherein a first surface of the second chip is electrically connected to the second wiring layer, and the packaging structure further comprises a second filling adhesive layer and a second conductive member, wherein the second filling adhesive layer is connected to the first dielectric layer and covers the second chip and the second conductive member, a first end of the second conductive member is electrically connected to the second wiring layer, a second surface of the second chip and a second end of the second conductive member are exposed from a surface of the second filling adhesive layer, the second surface of the second chip is opposite to the first surface of the second chip, and the first surface of the second chip is an electrical connection surface of the second chip.

6. The packaging structure according to claim 5, wherein the packaging structure further comprises a second dielectric layer and a third wiring layer, the second dielectric layer is arranged on the second filling adhesive layer and covers the second surface of the second chip and the second end of the second conductive member, the third wiring layer is arranged in the second dielectric layer, and the second end of the second conductive member is electrically connected to the third wiring layer.

7. The packaging structure according to claim 6, wherein the packaging structure further comprises a third conductive member, the third conductive member is arranged on a side of the second dielectric layer facing away from the first conductive member, and a first end of the third conductive member is electrically connected to the third wiring layer.

8. An electronic device, comprising a packaging structure, wherein the packaging structure comprises a substrate, a first chip, a first conductive member, and a first filling adhesive layer, wherein:
a groove is provided on the substrate, a first wiring layer is arranged on a bottom wall of the groove, the first chip is arranged in the groove, a first surface of the first chip is electrically connected to the first wiring layer, one end of the first conductive member is electrically connected to the first wiring layer, the first filling adhesive layer is filled in the groove, and the first filling adhesive layer is flush with a surface on which a notch of the groove is located; and
both the other end of the first conductive member and a second surface of the first chip are exposed from the first filling adhesive layer, and are flush with the surface on which the notch of the groove is located, the first surface of the first chip is opposite to the second surface of the first chip, and the first surface of the first chip is an electrical connection surface of the first chip.

9. The electronic device according to claim 8, wherein the packaging structure further comprises a first dielectric layer and a second wiring layer, the first dielectric layer is arranged on the substrate and covers the notch of the groove, the second wiring layer is arranged in the first dielectric layer, and the other end of the first conductive member is electrically connected to the second wiring layer.

10. The electronic device according to claim 9, wherein a quantity of grooves, a quantity of first chips, and a quantity of first conductive members are more than one, the grooves are spaced apart, the first chips are arranged in the grooves in a one-to-one correspondence, the first conductive members surrounding the corresponding first chip are arranged in each of the grooves, and the other ends of the first conductive members are electrically connected through the second wiring layer.

11. The electronic device according to claim 9, wherein the packaging structure further comprises a second chip, the second chip is arranged on a side of the first dielectric layer facing away from the first chip, and the second chip is electrically connected to the second wiring layer.

12. The electronic device according to claim 11, wherein a first surface of the second chip is electrically connected to the second wiring layer, and the packaging structure further comprises a second filling adhesive layer and a second conductive member, wherein the second filling adhesive layer is connected to the first dielectric layer and covers the second chip and the second conductive member, a first end of the second conductive member is electrically connected to the second wiring layer, a second surface of the second chip and a second end of the second conductive member are exposed from a surface of the second filling adhesive layer, the second surface of the second chip is opposite to the first surface of the second chip, and the first surface of the second chip is an electrical connection surface of the second chip.

13. The electronic device according to claim 12, wherein the packaging structure further comprises a second dielectric layer and a third wiring layer, the second dielectric layer is arranged on the second filling adhesive layer and covers the second surface of the second chip and the second end of the second conductive member, the third wiring layer is arranged in the second dielectric layer, and the second end of the second conductive member is electrically connected to the third wiring layer.

14. The electronic device according to claim 13, wherein the packaging structure further comprises a third conductive member, the third conductive member is arranged on a side of the second dielectric layer facing away from the first conductive member, and a first end of the third conductive member is electrically connected to the third wiring layer.

15. A method for preparing a packaging structure, comprising:
providing a groove on a substrate;
preparing a first wiring layer on a bottom wall of the groove;
arranging a first chip in the groove, and electrically connecting a first surface of the first chip to the first wiring layer;
preparing a first conductive member, wherein one end of the first conductive member is electrically connected to the first wiring layer;
filling an adhesive in the groove to form a first filling adhesive layer, wherein the first filling adhesive layer at least covers a notch of the groove; and
performing grinding processing on a side of the first filling adhesive layer facing away from the substrate, to enable the first filling adhesive layer to be flush with a surface on which the notch of the groove is located, and enable the other end of the first conductive member and a second surface of the first chip to be exposed from the first filling adhesive layer, wherein the first surface of the first chip is opposite to the second surface of the first chip.

16. The method according to claim 15, wherein:
after the performing grinding processing on a side of the first filling adhesive layer facing away from the substrate, the method further comprises:
preparing a first dielectric layer and a second wiring layer on the substrate, wherein the first dielectric layer covers the notch of the groove, the second wiring layer is located in the first dielectric layer, and the other end of the first conductive member is electrically connected to the second wiring layer, wherein
a second chip is arranged on a side of the first dielectric layer facing away from the first chip, and a first surface of the second chip is electrically connected to the second wiring layer;
preparing a second conductive member, wherein one end of the second conductive member is electrically connected to the second wiring layer;
preparing a second filling adhesive layer on the first dielectric layer, wherein the second filling adhesive layer covers the second chip and the second conductive member; and
performing grinding processing on a side of the second filling adhesive layer facing away from the substrate, to enable a second surface of the second chip, a second end of the second conductive member, and the second filling adhesive layer to be flush with each other, and enable the second surface of the second chip and the second end of the second conductive member to be exposed from the second filling adhesive layer, wherein the first surface of the second chip is opposite to the second surface of the second chip.
